(19) United States
(12) Patent Application Publication
(10) Pub. No.: US 2026/0110749 A1
(43) Pub. Date: Apr. 23, 2026

(54) BATTERY MANAGEMENT APPARATUS, BATTERY MANAGEMENT METHOD, AND NON-TRANSITORY COMPUTER-READABLE MEDIUM

(71) Applicant: TOYOTA JIDOSHA KABUSHIKI KAISHA, Toyota-shi (JP)

(72) Inventors: Yoshiaki KIKUCHI, Toyota-shi (JP); Ryo MANO, Nisshin-shi (JP); Hiroaki TASHIRO, Nisshin-shi (JP); Yuji NISHI, Nagoya-shi (JP); Keisuke ISHIKAWA, Nagakute-shi (JP)

(73) Assignee: TOYOTA JIDOSHA KABUSHIKI KAISHA, Toyota-shi (JP)

(21) Appl. No.: 19/354,686

(22) Filed: Oct. 9, 2025

(30) Foreign Application Priority Data
Oct. 17, 2024 (JP) 2024-181983

(51) Int. Cl. G01R 31/389; G01R 31/367; G01R 31/392; H01M 10/0525; H02J 7/00

(52) U.S. Cl. CPC G01R 31/389; G01R 31/367; G01R 31/392; H02J 7/65; H02J 7/977; H01M 10/0525

(57) ABSTRACT

A battery management apparatus according to the present disclosure includes: a temperature detection unit configured to detect a temperature of a lithium-ion secondary battery; a high-frequency signal supply unit configured to supply a high-frequency signal of 0.1 MHz or higher to the lithium-ion secondary battery; an impedance detection unit configured to detect a value of a real part of an AC impedance from the lithium-ion secondary battery to which the high-frequency signal has been supplied; a calculation unit configured to calculate an amount of Li precipitation in the lithium-ion secondary battery from the detected value of the real part of the AC impedance; and a control unit configured to, based on the calculated amount of Li precipitation in the lithium-ion secondary battery, control an allowable charging power for the lithium-ion secondary battery and control an upper limit temperature of the lithium-ion secondary battery.

### CROSS REFERENCE TO RELATED APPLICATIONS

This application is based upon and claims the benefit of priority from Japanese patent application No. 2024-181983, filed on Oct. 17, 2024, the disclosure of which is incorporated herein in its entirety by reference.

### BACKGROUND

The present disclosure relates to a battery management apparatus, a battery management method, and a control program.

In order to prevent the deterioration of the performance of a lithium-ion secondary battery, there has been a demand to suppress precipitation of metallic Li (lithium) (hereinafter referred to as Li precipitation) in the lithium-ion secondary battery. However, a method for detecting Li precipitation in a lithium-ion secondary battery in a nondestructive manner is not known.

In order to address the above demand, as disclosed in Patent Literature 1, the inventors have developed a method for detecting a real part of an AC impedance of a lithium-ion secondary battery using a high-frequency signal, and calculating the amount of Li precipitation in the lithium-ion secondary battery based on a difference between the current value and the initial value of the real part of the AC impedance.

[Patent Literature 1] Japanese Unexamined Patent Application Publication No. 2022-108602

### SUMMARY

Since Li precipitation progresses as a charging power increases, an allowable charging power is set for each type of the lithium-ion secondary battery in order to suppress Li precipitation. Note that even in the products of the same type, there are variations (e.g., a standard deviation σ) from product to product in the speed at which Li precipitation progresses in the lithium-ion secondary battery. In the lithium-ion secondary battery in the related art, an allowable charging power is set (fixed) excessively low for each type of the products included in the range of, for example, ±6σ, in order to prevent Li precipitation from progressing, and hence there is a problem that charging time increases.

The present disclosure has been made in view of the aforementioned circumstances and an object thereof is to provide a battery management apparatus, a battery management method, and a control program by which it is possible to efficiently charge a lithium-ion secondary battery.

A battery management apparatus according to the present disclosure includes: a temperature detection unit configured to detect a temperature of a lithium-ion secondary battery; a high-frequency signal supply unit configured to supply a high-frequency signal of 0.1 MHz or higher to the lithium-ion secondary battery; an impedance detection unit configured to detect a value of a real part of an AC impedance from the lithium-ion secondary battery to which the high-frequency signal has been supplied; a calculation unit configured to calculate an amount of Li precipitation in the lithium-ion secondary battery from the detected value of the real part of the AC impedance; and a control unit configured to, based on the calculated amount of Li precipitation in the lithium-ion secondary battery, control an allowable charging power for the lithium-ion secondary battery and control an upper limit temperature of the lithium-ion secondary battery, the upper limit temperature being a temperature used as a criterion for determining whether or not the lithium-ion secondary battery may reach an overheated state. The battery management apparatus according to the present disclosure calculates the amount of Li precipitation in the lithium-ion secondary battery from the value of the real part of the AC impedance detected from the lithium-ion secondary battery to which the high-frequency signal has been supplied, and feedback-controls the allowable charging power for the lithium-ion secondary battery based on the calculated result. Thus, the battery management apparatus according to the present disclosure can set the allowable charging power for the lithium-ion secondary battery to an appropriate value in accordance with the amount of Li precipitation without setting it to an excessively low value, and therefore it is possible to efficiently charge the lithium-ion secondary battery. Further, the battery management apparatus according to the present disclosure controls the upper limit temperature of the lithium-ion secondary battery (a temperature used as a criterion for determining whether or not the lithium-ion secondary battery may reach an overheated state) in accordance with the amount of Li precipitation by taking into account the decrease in the resistance to overheating of the lithium-ion secondary battery due to Li precipitation, thereby enabling the lithium-ion secondary battery to be accurately prevented from overheating.

The high-frequency signal supply unit may supply the high-frequency signal of 0.5 MHz or higher to the lithium-ion secondary battery.

The control unit may limit charging of the lithium-ion secondary battery when the temperature of the lithium-ion secondary battery reaches the upper limit temperature.

The control unit may control the allowable charging power for the lithium-ion secondary battery in such a manner that the allowable charging power decreases as the calculated amount of Li precipitation in the lithium-ion secondary battery increases and control the upper limit temperature of the lithium-ion secondary battery in such a manner that the upper limit temperature decreases as the calculated amount of Li precipitation in the lithium-ion secondary battery increases.

The control unit may control an upper limit temperature of each of a plurality of stacked battery cells constituting the lithium-ion secondary battery based on an amount of Li precipitation in a corresponding one of the plurality of battery cells.

The control unit may control the upper limit temperature of each of the battery cells in such a manner that the upper limit temperature decreases as the calculated amount of Li precipitation in a corresponding one of the battery cells increases.

The temperature detection unit may include at least one thermistor configured to detect a temperature of at least one of the plurality of battery cells, and the temperature detection unit may estimate a temperature of each of the plurality of battery cells based on a result of the detection by the at least one thermistor and a cell voltage of a corresponding one of the plurality of battery cells.

In a battery management method according to the present disclosure, a battery management apparatus: supplies a high-frequency signal of 0.1 MHz or higher to a lithium-ion secondary battery; detects a value of a real part of an AC impedance from the lithium-ion secondary battery to which the high-frequency signal has been supplied; calculates an amount of Li precipitation in the lithium-ion secondary battery from the detected value of the real part of the AC impedance; controls an allowable charging power for the lithium-ion secondary battery based on the calculated amount of Li precipitation in the lithium-ion secondary battery; and controls an upper limit temperature of the lithium-ion secondary battery based on the calculated amount of Li precipitation in the lithium-ion secondary battery, the upper limit temperature being a temperature used as a criterion for determining whether or not the lithium-ion secondary battery may reach an overheated state. In the battery management method according to the present disclosure, the amount of Li precipitation in the lithium-ion secondary battery is calculated from the value of the real part of the AC impedance detected from the lithium-ion secondary battery to which the high-frequency signal has been supplied, and the allowable charging power for the lithium-ion secondary battery is feedback-controlled based on the calculated result. Thus, in the battery management method according to the present disclosure, the allowable charging power for the lithium-ion secondary battery can be set to an appropriate value in accordance with the amount of Li precipitation without setting it to an excessively low value, and therefore it is possible to efficiently charge the lithium-ion secondary battery. Further, in the battery management method according to the present disclosure, the upper limit temperature of the lithium-ion secondary battery (a temperature used as a criterion for determining whether or not the lithium-ion secondary battery may reach an overheated state) is controlled in accordance with the amount of Li precipitation by taking into account the decrease in the resistance to overheating of the lithium-ion secondary battery due to Li precipitation, to thereby enable the lithium-ion secondary battery to be accurately prevented from overheating.

A control program according to the present disclosure causes a computer to: supply a high-frequency signal of 0.1 MHz or higher to a lithium-ion secondary battery; detect a value of a real part of an AC impedance from the lithium-ion secondary battery to which the high-frequency signal has been supplied; calculate an amount of Li precipitation in the lithium-ion secondary battery from the detected value of the real part of the AC impedance; control an allowable charging power for the lithium-ion secondary battery based on the calculated amount of Li precipitation in the lithium-ion secondary battery; and control an upper limit temperature of the lithium-ion secondary battery based on the calculated amount of Li precipitation in the lithium-ion secondary battery, the upper limit temperature being a temperature used as a criterion for determining whether or not the lithium-ion secondary battery may reach an overheated state. The control program according to the present disclosure calculates the amount of Li precipitation in the lithium-ion secondary battery from the value of the real part of the AC impedance detected from the lithium-ion secondary battery to which the high-frequency signal has been supplied, and feedback-controls the allowable charging power for the lithium-ion secondary battery based on the calculated result. Thus, the control program according to the present disclosure can set the allowable charging power for the lithium-ion secondary battery to an appropriate value in accordance with the amount of Li precipitation without setting it to an excessively low value, and therefore it is possible to efficiently charge the lithium-ion secondary battery. Further, the control program according to the present disclosure controls the upper limit temperature of the lithium-ion secondary battery (a temperature used as a criterion for determining whether or not the lithium-ion secondary battery may reach an overheated state) in accordance with the amount of Li precipitation by taking into account the decrease in the resistance to overheating of the lithium-ion secondary battery due to Li precipitation, thereby enabling the lithium-ion secondary battery to be accurately prevented from overheating.

According to the present disclosure, it is possible to provide a battery management apparatus, a battery management method, and a control program by which it is possible to efficiently charge a lithium-ion secondary battery.

The above and other objects, features and advantages of the present disclosure will become more fully understood from the detailed description given hereinbelow and the accompanying drawings.

### BRIEF DESCRIPTION OF DRAWINGS

FIG. 1 is a block diagram showing an example of a configuration of a battery management system according to the present disclosure;

FIG. 2 is a diagram showing a relationship between an SOH of a secondary battery and the amount of change in a real part Z of an AC impedance when a high-frequency signal of 1 MHz is supplied to the secondary battery;

FIG. 3 is a diagram showing a relationship between a frequency of an AC signal supplied to the secondary battery and the real part of the AC impedance detected from the secondary battery;

FIG. 4 is a diagram showing a relationship between the frequency of the AC signal supplied to the secondary battery and the real part of the AC impedance detected from the secondary battery; and

FIG. 5 is a flowchart showing operations performed by a battery management apparatus according to the present disclosure.

### DESCRIPTION OF EMBODIMENTS

Specific embodiments to which the present disclosure is applied will be described hereinafter in detail with reference to the drawings. However, the present disclosure is not limited to the following embodiments. Further, for the clarification of the description, the following descriptions and the drawings are simplified as appropriate.

### First Embodiment

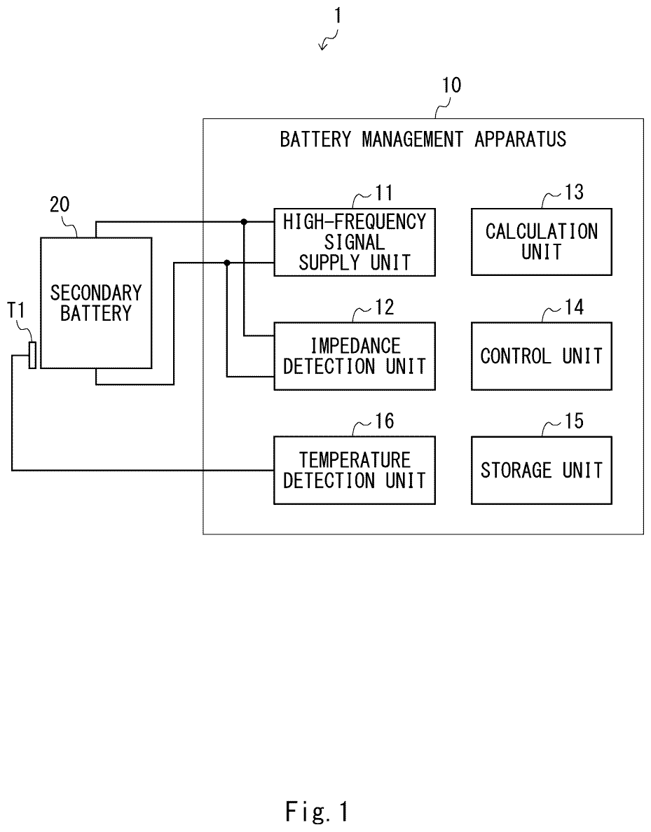

FIG. 1 is a block diagram showing an example of a configuration of a battery management system according to a first embodiment. As shown in FIG. 1, a battery management system 1 includes a battery management apparatus 10 and a secondary battery 20 managed by the battery management apparatus 10.

The secondary battery 20 is a lithium-ion secondary battery, and includes a cell stack composed of a plurality of stacked battery cells and a case for accommodating the cell stack.

Each of the battery cells includes a positive electrode, a negative electrode, and an ion transmission medium which is provided between the positive electrode and the negative electrode and conducts carrier ions. A separator may be further provided between the positive electrode and the negative electrode. A resin such as polyethylene or polypropylene is used as the separator.

For example, a sulfide containing a transition metal element, an oxide containing lithium and a transition metal element, or the like is used as a positive electrode active material. Specifically, a lithium manganese composite oxide in which a basic composition formula is, for example, Li₍₁₋ₓ₎MnO₂ (where 0<x<1), Li₍₁₋ₓ₎Mn₂O₄, a lithium cobalt composite oxide in which a basic composition formula is, for example, Li₍₁₋ₓ₎ CoO₂, a lithium nickel composite oxide in which a basic composition formula is, for example, Li₍₁₋ₓ₎NiO₂, a lithium nickel cobalt manganese composite oxide in which a basic composition formula is, for example, Li₍₁₋ₓ₎NiₐCo_{b}Mn_{c}O₂ (where a+b+c=1), or the like is used as a positive electrode active material. Note that a material in which other elements are contained in the above-mentioned basic composition formula may be used as a positive electrode active material. For example, Al (aluminum) is used as a current collector of a positive electrode.

For example, a composite oxide containing lithium, a carbon material, or the like is used as a negative electrode active material. Specifically, an inorganic compound such as lithium, a lithium alloy, and a tin compound, a carbon material capable of occluding and releasing lithium ions, a composite oxide containing a plurality of elements, a conductive polymer, or the like is used as a negative electrode active material. Examples of the carbon material used as a negative electrode active material include cokes, glassy carbons, graphites, non-graphitizable carbons, pyrolytic carbons, and a carbon fiber, and it is preferred that graphites such as artificial graphite or natural graphite be used. Further, examples of the composite oxide used as a negative electrode active material include a lithium titanium composite oxide and a lithium vanadium composite oxide. For example, Cu (copper) is used as a current collector of a negative electrode.

An ion-conducting medium is used as an electrolyte, for example, by dissolving a supporting salt. For example, a lithium salt such as LiPF₆ and LiBF₄ is used as a supporting salt. For example, one of carbonates, esters, ethers, nitriles, furans, sulfolanes, and dioxolanes or a mixture of some of them is used as a solvent of an electrolyte. Examples of the carbonates include cyclic carbonates such as ethylene carbonate, propylene carbonate, vinylene carbonate, butylene carbonate, and chloroethylene carbonate, and chain carbonates such as dimethyl carbonate, ethyl methyl carbonate, diethyl carbonate, ethyl-n-butyl carbonate, methyl-t-butyl carbonate, di-i-propyl carbonate, and t-butyl-i-propyl carbonate. Alternatively, a solid ion-conducting polymer, an inorganic solid electrolyte, a mixed material of an organic polymer electrolyte and an inorganic solid electrolyte, an inorganic solid powder bonded by an organic binder, or the like may be used as the ion-conducting medium.

The battery management apparatus 10 manages the charging of the secondary battery 20 to be managed. For example, the battery management apparatus 10 detects the amount of Li precipitation in the secondary battery 20 in a nondestructive manner, and feedback-controls an allowable charging power (an upper limit value of the charging power) Pa for the secondary battery 20 based on a result of the detection. Further, the battery management apparatus 10 detects the temperature of the secondary battery 20, and feedback-controls an upper limit temperature Ta, which is a temperature used as a criterion for determining whether or not the secondary battery 20 may reach an overheated state, based on a result of the detection.

The battery management apparatus 10 includes a high-frequency signal supply unit 11, an impedance detection unit 12, a calculation unit 13, a control unit 14, a storage unit 15, and a temperature detection unit 16.

The high-frequency signal supply unit 11 supplies a high-frequency signal to the secondary battery 20. The impedance detection unit 12 detects the value of a real part Z of an AC impedance from the secondary battery 20 to which the high-frequency signal has been supplied.

It should be noted that, in the secondary battery 20, metal Li is precipitated in the electrode surface of each of the battery cells by repeatedly charging the secondary battery 20. The Li precipitation progresses as the charging power is increased in order to increase the charging speed, and hence a state of health (SOH) of the secondary battery 20 deteriorates. Note that the SOH of the secondary battery 20 is a percentage of the current capacity when it is assumed that the initial capacity of the secondary battery 20 is 100%. Therefore, it is desirable to set for the secondary battery 20 the highest possible allowable charging power Pa which enables the secondary battery 20 to be efficiently charged in the shortest possible charging time while suppressing Li precipitation.

Note that when an AC signal (a high-frequency signal) of a high frequency with which the diffusion, reaction, and movement of lithium ions cannot be followed in each of the battery cells of the secondary battery 20 is supplied to the secondary battery 20, the current of the high-frequency signal flows along the edge of a conductor of each of the battery cells due to skin effect. In other words, the current of the high-frequency signal flows through an electrode surface of each of the battery cells where Li precipitation easily occurs due to skin effect. Further, even when Li metal is electrically disconnected from the negative electrode after Li precipitation and brought into a float state, the current flows on the Li metal by inductive coupling and electric field coupling. Therefore, for example, as the amount of Li precipitation decreases, the electric conductivity of the electrode surface of each of the battery cells decreases, and thus the value of the real part Z of the AC impedance increases. Further, as the amount of Li precipitation increases, the electric conductivity of the electrode surface of each of the battery cells increases, and thus the value of the real part Z of the AC impedance decreases. Note that since a large amount of current concentrates on Li metal having a high conductivity, the magnetic field changes around an Li precipitation region, and as a result, an eddy current is generated. This eddy current causes a loss in a current collecting foil and a conductive part of the electrode. However, a loss of the battery as a whole is reduced. Therefore, as the amount of Li precipitation increases, the change of the magnetic field increases. As a result, the eddy current increases, and thus the value of the real part Z decreases. Therefore, it is possible to calculate the amount of Li precipitation in the secondary battery 20 from the value of the real part Z of the AC impedance detected from the secondary battery 20 to which a high-frequency signal has been supplied. If the amount of Li precipitation is known, the SOH of the secondary battery 20 can be estimated.

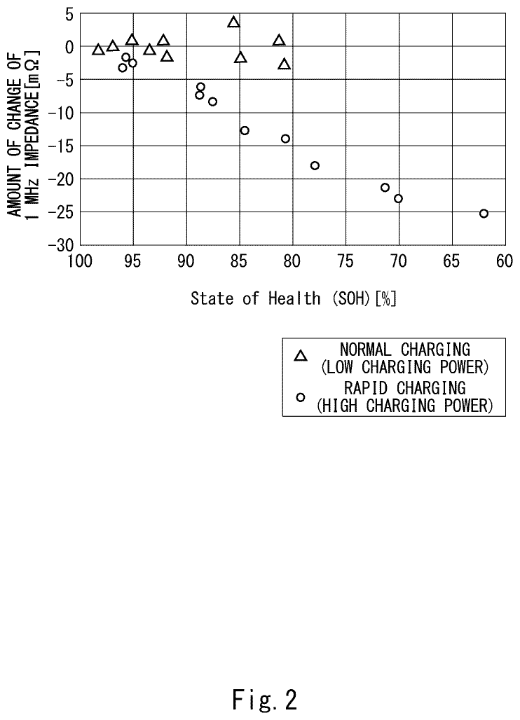

FIG. 2 is a diagram showing a relationship between the SOH of the secondary battery 20 and the amount of change (a difference between a detected value and the initial value) of the real part Z of the AC impedance when a high-frequency signal of 1 MHz is supplied to the secondary battery 20. As indicated by triangles in FIG. 2, in the case of a normal charging where the charging power is low, the amount of Li precipitation is low even if charging is repeated. Thus, the amount of change of the real part Z of the AC impedance remains small even if the degradation of the SOH progresses due to other factors (i.e., the detected value of the real part Z of the AC impedance is maintained high). On the other hand, as indicated by circles in FIG. 2, in the case of a rapid charging where the charging power is high, the amount of amount of Li precipitation increases when charging is repeated. As a result, the degradation of the SOH progresses, and thus the amount of change of the real part Z of the AC impedance increases (i.e., the detected value of the real part Z of the AC impedance is low). Note that, in a case where battery degradation due to Li precipitation is a dominant factor of battery degradation, the amount of Li precipitation can be derived from the SOH. Alternatively, the SOH can be derived from the amount of Li precipitation.

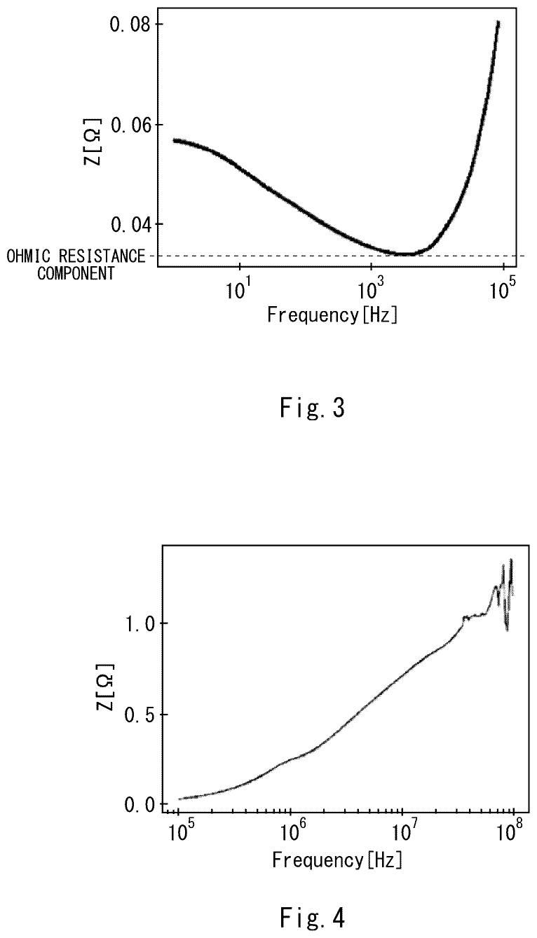

Each of FIGS. 3 and 4 is a diagram showing a relationship between a frequency of an AC signal supplied to the secondary battery 20 and the real part of the AC impedance detected by the secondary battery 20. FIG. 3 shows the values of the real part Z of the AC impedance when AC signals of 1 kHz to 100 kHz are supplied to the secondary battery 20. FIG. 4 shows the values of the real part Z of the AC impedance when AC signals of 100 kHz to 100 MHz are supplied to the secondary battery 20.

As shown in FIG. 3, when an AC signal of about 1 kHz is supplied to the secondary battery 20, the value of the real part Z of the AC impedance is the minimum value. The impedance component at this time indicates the ohmic resistance component. Further, as shown in FIGS. 3 and 4, the higher the frequency of the AC signal supplied to the secondary battery 20, the more the current flow is concentrated in the electrode surface of each of the cells due to skin effect, and thus the value of the real part Z of the AC impedance increases.

Therefore, the high-frequency signal supply unit 11 supplies, to the secondary battery 20, an AC signal of a high frequency (i.e., a high-frequency signal) with which a value of the real part Z of the AC impedance sufficiently higher than the ohmic resistance component can be detected. For example, the high-frequency signal supply unit 11 supplies a high-frequency signal of 0.1 MHz or higher to the secondary battery 20. In the examples shown in FIGS. 3 and 4, the high-frequency signal supply unit 11 supplies a high-frequency signal of 0.5 MHz or higher to the secondary battery 20. Thus, the current of the high-frequency signal flows through the electrode surface (the Li precipitation region) of each of the battery cells of the secondary battery 20 due to skin effect. Thus, the impedance detection unit 12 can detect the real part Z of the AC impedance corresponding to the amount of Li precipitation.

The calculation unit 13 calculates the amount of Li precipitation in the secondary battery 20 from the value of the real part Z of the AC impedance detected by the impedance detection unit 12. More specifically, the calculation unit 13 calculates the amount of Li precipitation in the secondary battery 20 based on a difference between the current value of the real part Z of the AC impedance detected by the impedance detection unit 12 and the initial value of the real part Z of the AC impedance of the secondary battery 20. Information about the initial value of the real part Z of the AC impedance of the secondary battery 20 to be managed is stored, for example, in the storage unit 15.

For example, the calculation unit 13 calculates a smaller amount of Li precipitation as the detected value of the real part Z of the AC impedance becomes larger, while it calculates a larger amount of Li precipitation as the detected value of the real part Z of the AC impedance becomes smaller.

Note that information about the initial value of the real part Z of the AC impedance of the secondary battery of each type may be stored in the storage unit 15. Further, map information indicating a relationship between a difference (an amount of change) between the current value (the detected value) and the initial value of the real part Z of the AC impedance of the secondary battery of each type and the amount of Li precipitation may be stored in the storage unit 15. This map information is, for example, information obtained in advance by an experiment, and may be updated as appropriate based on information detected from the secondary battery 20 to be managed. In this case, the calculation unit 13 extracts the amount of Li precipitation corresponding to the value of the real part Z of the AC impedance detected by the impedance detection unit 12 from the map information stored in the storage unit 15.

The control unit 14 controls the allowable charging power Pa for the secondary battery 20 based on the amount of Li precipitation calculated by the calculation unit 13. For example, when the calculated amount of Li precipitation is small, the control unit 14 maintains the allowable charging power Pa as it is or controls it in such a manner that it increases, because the progress of Li precipitation is suppressed. Moreover, the control unit 14 controls the allowable charging power Pa in such a manner that it decreases as the calculated amount of Li deposition increases, because it is necessary to suppress the progress of Li precipitation. Note that the control unit 14 may switch the allowable charging power Pa in a stepwise manner in accordance with the calculated amount of Li precipitation.

By doing so, the battery management apparatus 10 according to the present disclosure can set for the secondary battery 20 the highest possible allowable charging power Pa which enables the secondary battery 20 to be efficiently charged in the shortest possible charging time while suppressing Li precipitation. That is, the battery management apparatus 10 according to the present disclosure can set the allowable charging power Pa for the secondary battery 20 to an appropriate value in accordance with the amount of Li precipitation without setting it to an excessively low value, and therefore it is possible to efficiently charge the secondary battery 20.

The temperature detection unit 16 detects the temperature of the secondary battery 20. For example, the temperature detection unit 16 detects the temperature of at least one of a plurality of battery cells constituting the secondary battery 20 by using at least one thermistor T1. Further, the temperature detection unit 16 calculates a resistance value of each of the plurality of battery cells from the cell voltage of a corresponding one of the plurality of battery cells. Then the temperature detection unit 16 calculates a difference between the amount of heat generation of each of the plurality of battery cells and the amount of heat generation of the battery cell to which the thermistor T1 is attached from the difference between the calculated resistance value of each of the plurality of battery cells and the resistance value of the battery cell to which the thermistor T1 is attached, and estimates the temperature of each of the plurality of battery cells based on results of the calculation.

When the temperature of the secondary battery 20 detected by the temperature detection unit 16 reaches the upper limit temperature Ta, the control unit 14 determines that the secondary battery 20 may reach an overheated state, and limits (e.g., stops) the charging of the secondary battery 20. The upper limit temperature Ta is a temperature used as a criterion for determining whether or not the secondary battery 20 may reach an overheated state.

Note that it is known that the resistance to overheating of the secondary battery 20 decreases as Li precipitation progresses. Therefore, the control unit 14 controls not only the allowable charging power Pa for the secondary battery 20 but also the upper limit temperature Ta of the secondary battery 20, which is a temperature used as a criterion for determining whether or not the secondary battery 20 may reach an overheated state, based on the amount of Li precipitation in the secondary battery 20.

For example, the control unit 14 maintains the upper limit temperature Ta of the secondary battery 20 as it is when the calculated amount of Li precipitation is small, because the value of the resistance to overheating of the secondary battery 20 is maintained high, while the control unit 14 decreases the upper limit temperature Ta of the secondary battery 20, because the resistance to overheating of the secondary battery 20 decreases as the calculated amount of Li precipitation increases. Note that the control unit 14 may gradually decrease the upper limit temperature Ta of the secondary battery 20 to, for example, the initial values of 130 degrees, 120 degrees, and 110 degrees as the amount of Li precipitation increases.

By doing so, the battery management apparatus 10 according to the present disclosure can accurately prevent overheating of the secondary battery 20. Note that the control unit 14 may individually control the upper limit temperatures Ta of a plurality of battery cells constituting the secondary battery 20 based on the respective amounts of Li precipitation in the plurality of battery cells. In this case, the control unit 14 controls the upper limit temperature Ta of the battery cell in such a manner that it decreases as the calculated amount of Li precipitation in the battery cell increases.

### Operation of the Battery Management Apparatus 10

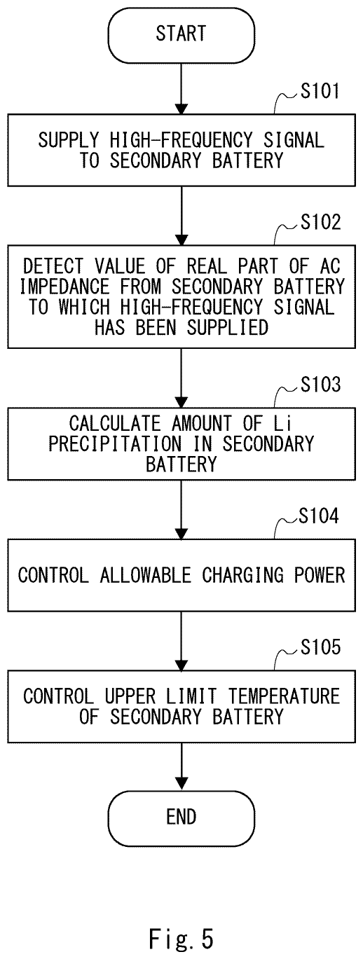

Next, operations performed by the battery management apparatus 10 will be described with reference to FIG. 5. FIG. 5 is a flowchart showing the operations performed by the battery management apparatus 10.

First, the battery management apparatus 10 supplies an AC signal (a high-frequency signal) of a high frequency with which the diffusion, reaction, and movement of lithium ions cannot be followed in each of the battery cells to the secondary battery 20 (Step S101). For example, the battery management apparatus 10 supplies a high-frequency signal of 0.1 MHz or higher to the secondary battery 20. Then the battery management apparatus 10 detects a value of the real part Z of the AC impedance from the secondary battery 20 to which the high-frequency signal has been supplied (Step S102).

After that, the battery management apparatus 10 calculates the amount of Li precipitation in the secondary battery 20 from the detected value of the real part Z of the AC impedance (Step S103). For example, the battery management apparatus 10 extracts the amount of Li precipitation corresponding to the detected value of the real part Z of the AC impedance from map information stored in the storage unit 15. Basically, the battery management apparatus 10 calculates a smaller amount of Li precipitation as the detected value of the real part Z of the AC impedance becomes larger, while it calculates a larger amount of Li precipitation as the detected value of the real part Z of the AC impedance becomes smaller.

After that, the battery management apparatus 10 controls the allowable charging power Pa for the secondary battery 20 based on the calculated amount of Li precipitation (Step S104). For example, when the calculated amount of Li precipitation is small, the battery management apparatus 10 maintains the allowable charging power Pa as it is or controls it in such a manner that it increases, because the progress of Li precipitation is suppressed. Moreover, the battery management apparatus 10 controls the allowable charging power Pa in such a manner that it decreases as the calculated amount of Li deposition increases, because it is necessary to suppress the progress of Li precipitation.

Further, the battery management apparatus 10 controls the upper limit temperature Ta of the secondary battery 20, which is a temperature used as a criterion for determining whether or not the secondary battery 20 may reach an overheated state, based on the calculated amount of Li precipitation (Step S105). For example, the battery management apparatus 10 maintains the upper limit temperature Ta of the secondary battery 20 as it is when the calculated amount of Li precipitation is small, because the value of the resistance to overheating of the secondary battery 20 is maintained high, while the battery management apparatus 10 decreases the upper limit temperature Ta of the secondary battery 20, because the resistance to overheating of the secondary battery 20 decreases as the calculated amount of Li precipitation increases.

As described above, the battery management apparatus 10 according to the present disclosure can set for the secondary battery 20 the highest possible allowable charging power Pa which enables the secondary battery 20 to be efficiently charged in the shortest possible charging time while suppressing Li precipitation. That is, the battery management apparatus 10 according to the present disclosure can set the allowable charging power Pa for the secondary battery 20 to an appropriate value in accordance with the amount of Li precipitation without setting it to an excessively low value, and therefore it is possible to efficiently charge the secondary battery 20.

Further, the battery management apparatus 10 according to the present disclosure controls the upper limit temperature Ta (a temperature used as a criterion for determining whether or not the lithium-ion secondary battery may reach an overheated state) of a lithium-ion secondary battery in accordance with the amount of Li precipitation by taking into account the decrease in the resistance to overheating of the lithium-ion secondary battery due to Li precipitation, thereby enabling the lithium-ion secondary battery to be accurately prevented from overheating.

In the present disclosure, an example of a case where the temperature detection unit 16 detects the secondary battery 20 by using the thermistor T1 and the cell voltages has been described. However, the present disclosure is not limited thereto. For example, the temperature detection unit 16 may be configured to detect the battery temperature of the thermistor T1 instead of detecting the temperature of the secondary battery 20. In this case, the control unit 14 gradually decreases the battery temperature of the thermistor T1 to, for example, the initial values of 60 degrees, 55 degrees, and 50 degrees as the amount of Li precipitation increases, thereby gradually decreasing the upper limit temperature Ta of the secondary battery 20.

Further, in the present disclosure, some or all of the processes performed by the battery management apparatus 10 may be implemented by causing a Central Processing Unit (CPU) to execute a computer program.

The above-described program includes instructions (or software codes) that, when loaded into a computer, cause the computer to perform one or more of the functions described in the embodiments. The program may be stored in a non-transitory computer readable medium or a tangible storage medium. By way of example, and not a limitation, non-transitory computer readable media or tangible storage media can include a Random-Access Memory (RAM), a Read-Only Memory (ROM), a flash memory, a Solid-State Drive (SSD) or other types of memory technologies, a CD-ROM, a Digital Versatile Disc (DVD), a Blu-ray (Registered Trademark) disc or other types of optical disc storage, a magnetic cassette, a magnetic tape, and a magnetic disk storage or other types of magnetic storage devices. The program may be transmitted on a transitory computer readable medium or a communication medium. By way of example, and not a limitation, transitory computer readable media or communication media can include electrical, optical, acoustical, or other forms of propagated signals.

Although the present disclosure has been described with reference to embodiments, the present disclosure is not limited to the above-described embodiments. Various changes that may be understood by those skilled in the art may be made to the configurations and details of the present disclosure within the scope of the present disclosure. Further, each of the embodiments may be combined with at least one of the other embodiments as appropriate.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A battery management apparatus comprising:
a temperature detection unit configured to detect a temperature of a lithium-ion secondary battery;
a high-frequency signal supply unit configured to supply a high-frequency signal of 0.1 MHz or higher to the lithium-ion secondary battery;
an impedance detection unit configured to detect a value of a real part of an AC impedance from the lithium-ion secondary battery to which the high-frequency signal has been supplied;
a calculation unit configured to calculate an amount of Li precipitation in the lithium-ion secondary battery from the detected value of the real part of the AC impedance; and
a control unit configured to, based on the calculated amount of Li precipitation in the lithium-ion secondary battery, control an allowable charging power for the lithium-ion secondary battery and control an upper limit temperature of the lithium-ion secondary battery, the upper limit temperature being a temperature used as a criterion for determining whether or not the lithium-ion secondary battery may reach an overheated state.

2. The battery management apparatus according to claim 1, wherein the high-frequency signal supply unit supplies the high-frequency signal of 0.5 MHz or higher to the lithium-ion secondary battery.

3. The battery management apparatus according to claim 1, wherein the control unit limits charging of the lithium-ion secondary battery when the temperature of the lithium-ion secondary battery reaches the upper limit temperature.

4. The battery management apparatus according to claim 1, wherein the control unit controls the allowable charging power for the lithium-ion secondary battery in such a manner that the allowable charging power decreases as the calculated amount of Li precipitation in the lithium-ion secondary battery increases and controls the upper limit temperature of the lithium-ion secondary battery in such a manner that the upper limit temperature decreases as the calculated amount of Li precipitation in the lithium-ion secondary battery increases.

5. The battery management apparatus according to claim 1, wherein the control unit controls an upper limit temperature of each of a plurality of stacked battery cells constituting the lithium-ion secondary battery based on an amount of Li precipitation in a corresponding one of the plurality of battery cells.

6. The battery management apparatus according to claim 5, wherein the control unit controls the upper limit temperature of each of the battery cells in such a manner that the upper limit temperature decreases as the calculated amount of Li precipitation in a corresponding one of the battery cells increases.

7. The battery management apparatus according to claim 5, wherein
the temperature detection unit comprises at least one thermistor configured to detect a temperature of at least one of the plurality of battery cells, and
the temperature detection unit estimates a temperature of each of the plurality of battery cells based on a result of the detection by the at least one thermistor and a cell voltage of a corresponding one of the plurality of battery cells.

8. A battery management method performed by a battery management apparatus, the battery management method comprising:
supplying a high-frequency signal of 0.1 MHz or higher to a lithium-ion secondary battery;
detecting a value of a real part of an AC impedance from the lithium-ion secondary battery to which the high-frequency signal has been supplied;
calculating an amount of Li precipitation in the lithium-ion secondary battery from the detected value of the real part of the AC impedance;
controlling an allowable charging power for the lithium-ion secondary battery based on the calculated amount of Li precipitation in the lithium-ion secondary battery; and
controlling an upper limit temperature of the lithium-ion secondary battery based on the calculated amount of Li precipitation in the lithium-ion secondary battery, the upper limit temperature being a temperature used as a criterion for determining whether or not the lithium-ion secondary battery may reach an overheated state.

9. A non-transitory computer readable medium storing a control program for causing a computer to:
supply a high-frequency signal of 0.1 MHz or higher to a lithium-ion secondary battery;
detect a value of a real part of an AC impedance from the lithium-ion secondary battery to which the high-frequency signal has been supplied;
calculate an amount of Li precipitation in the lithium-ion secondary battery from the detected value of the real part of the AC impedance;
control an allowable charging power for the lithium-ion secondary battery based on the calculated amount of Li precipitation in the lithium-ion secondary battery; and
control an upper limit temperature of the lithium-ion secondary battery based on the calculated amount of Li precipitation in the lithium-ion secondary battery, the upper limit temperature being a temperature used as a criterion for determining whether or not the lithium-ion secondary battery may reach an overheated state.
